(19) United States
(12) Patent Application Publication
(10) Pub. No.: US 2016/0056039 A1
(43) Pub. Date: Feb. 25, 2016

(54) METHOD OF FORMING A METAL SULFIDE ALLOY AND AN ELECTRONIC DEVICE WITH THE METAL SULFIDE ALLOY

(71) Applicant: Industry-Academic Cooperation Foundation, Yonsei University, Seoul (KR)

(72) Inventors: Hyungjun KIM, Seoul (KR); Jeong-Gyu SONG, Seoul (KR); Jusang PARK, Seoul (KR)

(21) Appl. No.: 14/703,091

(22) Filed: May 4, 2015

(30) Foreign Application Priority Data
Aug. 22, 2014 (KR) 10-2014-0109660

(51) Int. Cl. H01L 21/02; H01L 31/032; H01L 31/18; H01L 29/24; H01L 29/786

(52) U.S. Cl. CPC H01L 21/02568; H01L 21/02614; H01L 21/0262; H01L 29/24; H01L 29/786; H01L 31/18; H01L 31/032

(57) ABSTRACT

Example embodiments of the inventive concept relate to a method of forming a metal sulfide alloy. The method may include forming a metal oxide alloy on a substrate using an ALD process and transforming the metal oxide alloy to a metal sulfide alloy.

### CROSS-REFERENCE TO RELATED APPLICATIONS

This U.S. non-provisional patent application claims priority under 35 U.S.C. §119 to Korean Patent Application No. 10-2014-0109660, filed on Aug. 22, 2014, in the Korean Intellectual Property Office, the entire contents of which are hereby incorporated by reference.

### STATEMENT REGARDING PRIOR DISCLOSURES BY THE INVENTORS

The inventors of the present application authored and disclosed the subject matter of the present application on Nov. 19, 2013 (published online) and Dec. 23, 2013 (published as a treatise), and disclosed by oral presentations on Apr. 1, 2014 and Jun. 17, 2014. These prior disclosures have been submitted in an Information Disclosure Statement in the present application as “SONG, J-G., et al., Layer-Controlled, Wafer-Scale, and Conformal Synthesis of Tungsten Disulfide Nanosheets Using Atomic Layer Deposition, ACS Nano, Nov. 19, 2013 (online) and Dec. 23, 2013 (treatise), 7(12), pg. 11333-11340. (orally presented on Apr. 1, 2014 and Jun. 17, 2014).”

### BACKGROUND OF THE INVENTION

Example embodiments of the inventive concept relate to a method of forming a metal sulfide alloy and an electronic device with the metal sulfide alloy.

Some of metal sulfides exhibit a semiconductor property, and thus, a method of forming the metal sulfide is being studied. Until now, a conventional physical deposition process has been used to form the metal sulfide, but the use of the physical deposition process leads to difficulties in controlling deposition thickness and thickness uniformity of a metal sulfide layer.

To overcome such difficulties, the inventor of the present application has invented a method of forming a metal sulfide layer using an atomic layer deposition (ALD) process, as disclosed in Korean Patent Application No. 10-2014-0006786, filed on Jan. 20, 2014. The use of this method makes it possible to control a thickness of a metal sulfide layer and uniformly deposit a metal sulfide layer with a large area.

### SUMMARY

Example embodiments of the inventive concept provide methods for forming a metal sulfide alloy and for controlling a band gap of the metal sulfide alloy.

Other example embodiments of the inventive concept provide methods for forming a metal sulfide alloy, and in particular, of controlling a metal composition ratio thereof.

According to example embodiments of the inventive concept, a method for forming a metal sulfide alloy may include forming a metal oxide alloy on a substrate using an atomic layer deposition (ALD) process, and transforming the metal oxide alloy to a metal sulfide alloy.

In example embodiments, the forming of the metal oxide alloy may include a first step for forming molybdenum oxide (MoO₃) using an ALD process, and a second step for forming tungsten oxide (WO₃) using an ALD process. A process cycle comprising both the first and the second steps may be performed at least one time.

In example embodiments, the method may each of the first step and the second step comprise controlling a composition ratio of metals of the metal oxide alloy to adjust a band gap of the metal sulfide alloy.

In example embodiments, the composition ratio of metals of the metal oxide alloy may be controlled by changing the cycling numbers of the ALD processes in the first and the second steps.

In example embodiments, the first step may include supplying a molybdenum precursor comprising Mo(CO)₆ into an ALD chamber, and supplying an oxygen precursor into the ALD chamber.

In example embodiments, the second step may include supplying a tungsten precursor comprising WH₂(iPrCp)₂ into an ALD chamber, and supplying an oxygen precursor into the ALD chamber.

In example embodiments, the forming of the metal oxide alloy may comprise forming the metal oxide alloy having a chemical structure of Mo₍₁₋ₓ₎WₓO₃(0<x<1).

In example embodiments, the transforming of the metal oxide alloy to the metal sulfide alloy may include performing a thermal treatment on the substrate provided with the metal oxide alloy in an atmosphere of sulfur-containing gas and inert gas.

In example embodiments, the thermal treatment may be performed at a temperature of 600° C. to 1000° C. for 30 minutes to 60 minutes.

In example embodiments, in the thermal treatment, the sulfur-containing gas may be supplied at a flow rate of 10 sccm to 100 sccm and the inert gas may be supplied at a flow rate of 10 sccm to 100 sccm.

In example embodiments, the method may further include performing a heat treatment on the substrate provided with the metal oxide alloy in an atmosphere of hydrogen gas and inert gas, before the thermal treatment is performed.

In example embodiments, the heat treatment may be performed at a temperature of 200° C. to 600° C. for 30 minutes to 90 minutes.

In example embodiments, in the heat treatment, each of the hydrogen gas and the inert gas may be supplied at a flow rate of 10 sccm to 100 sccm.

In example embodiments, the method may further include cooling the substrate in an atmosphere of sulfur-containing gas and inert gas, after the thermal treatment.

In example embodiments, in the cooling of the substrate, each of the sulfur-containing gas and the inert gas may be supplied at a flow rate of 10 sccm to 100 sccm.

In example embodiments, the transforming of the metal oxide alloy to the metal sulfide alloy may be performed to transform the metal oxide alloy to the metal sulfide alloy having a chemical structure of Mo₍₁₋ₓ₎WₓS₂(0<x<1).

According to example embodiments of the inventive concept, a transistor may include a gate electrode on a substrate, a gate insulating material on the gate electrode, a channel layer on the gate insulating material, the channel layer comprising a metal sulfide alloy, and a source electrode on the channel layer and a drain electrode on the channel layer.

According to example embodiments of the inventive concept, a solar cell may include a first electrode on a substrate, an active layer on the first electrode, the active layer comprising a metal sulfide alloy, and a second electrode on the active layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic diagram illustrating a method of forming a metal sulfide alloy, according to example embodiments of the inventive concept.

FIG. 2 is a flow chart illustrating a process of depositing a metal oxide alloy using an ALD process, according to example embodiments of the inventive concept.

FIG. 3 is a flow chart illustrating a process of transforming the metal oxide alloy to a metal sulfide alloy, according to example embodiments of the inventive concept.

FIG. 4 is a graph showing a change in band gap of Mo₍₁₋ₓ₎WₓS₂ according to example embodiments of the inventive concept, depending on a metal composition ratio (i.e., Mo:W) thereof.

FIG. 5 is a table showing a ratio of molybdenum to tungsten in Mo₍₁₋ₓ₎WₓS₂, depending on a ratio in the cycling numbers of molybdenum oxide and tungsten oxide.

FIGS. 6A, 7A, and 8A are atomic force microscope (AFM) images obtained from Mo₍₁₋ₓ₎WₓS₂ layers according to first, second, and third embodiments of the inventive concept, and FIGS. 6B, 7B, and 8B are graphs showing spatial variations in thicknesses of thereof.

FIG. 9 is a diagram showing X-ray Photoelectron Spectroscopy (XPS) images obtained from metal sulfide alloys according to example embodiments of the inventive concept.

FIG. 10 is a sectional view illustrating an example of a transistor, according to example embodiments of the inventive concept.

FIG. 11 is a sectional view illustrating an example of a solar cell, according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Example embodiments of the inventive concept relate to a method of forming a metal sulfide alloy, and in particular, of forming a metal oxide alloy using an ALD process and performing a sulfuration process thereon to form a metal sulfide alloy.

The metal oxide alloy may be deposited by an ALD process, and thus, it is possible to control a thickness of the metal oxide alloy and moreover form a metal sulfide alloy with a large area and a uniform thickness. Also, the number of ALD cycling steps for forming each metal oxide may be controlled in the formation of the metal oxide alloy, and accordingly, it is possible to control a composition ratio of metals constituting the metal sulfide alloy and consequently to adjust a metal sulfide alloy with a controllable band gap. During the formation of the metal oxide alloy, a cycling step of forming each metal oxide may be repeated at least one time to obtain a desired thickness of the metal oxide alloy.

The metal sulfide alloy according to example embodiments of the inventive concept may be applied for a channel layer of a transistor or an active layer of a solar cell.

The metal sulfide alloy may include at least one of transition metals, such as Mo, W, Fe, Co, Ni, Ti, Nb, Hf, and Ta.

Hereinafter, a molybdenum tungsten sulfide alloy will be described as an example of the metal sulfide alloys according to example embodiments of the inventive concept, with reference to the accompanying drawings.

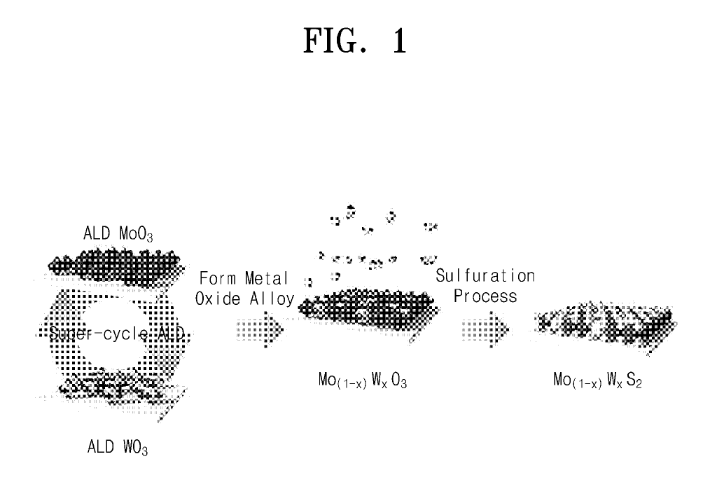

FIG. 1 is a schematic diagram illustrating a method of forming a metal sulfide alloy, according to example embodiments of the inventive concept.

As shown in FIG. 1, a method of forming a metal sulfide alloy may include forming a metal oxide alloy on a substrate using an ALD process and performing a sulfuration process on the metal oxide alloy to transform the metal oxide alloy to the metal sulfide alloy.

In exemplary embodiments, the method of forming a metal sulfide alloy may include depositing molybdenum oxide (MoO₃) and tungsten oxide (WO₃) on a substrate using an ALD process to form a metal oxide alloy of Mo₍₁₋ₓ₎WₓO₃ and sulfurating the metal oxide alloy to form a metal sulfide alloy of Mo₍₁₋ₓ₎WₓS₂.

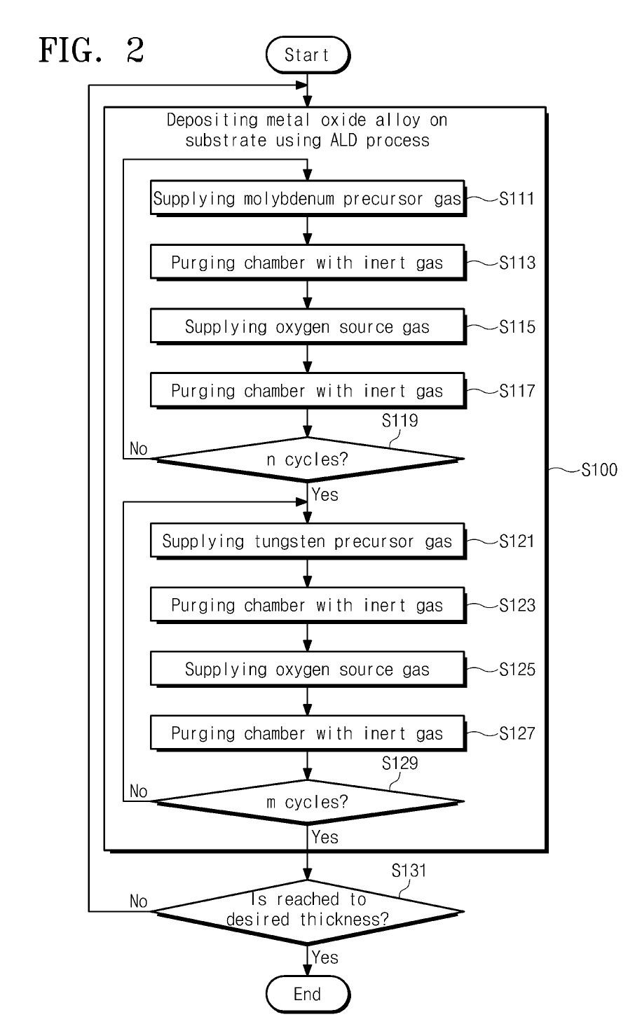

FIG. 2 is a flow chart illustrating a process, S100, of depositing a metal oxide alloy using an ALD process, according to example embodiments of the inventive concept.

As shown in FIG. 2, the forming of the metal oxide alloy may include a first step of forming molybdenum oxide (MoO₃) through an ALD process and a second step of forming tungsten oxide (WO₃) through an ALD process. Further, the forming of the metal oxide alloy may include a step S131 of controlling repetition of the step S100 until the metal oxide alloy has a desired thickness.

In exemplary embodiments, the first step may include a step S111 of supplying molybdenum precursor gas into a chamber, a step S113 of purging the chamber with inert gas, a step S115 of supplying oxygen source gas into the chamber, and a step S117 of purging the chamber with inert gas. Further, the forming of the metal oxide alloy may include a step S119 of controlling repetition of the first step until the total repetition number of the first step reaches a predetermined cycling number (e.g., n).

In detail, the step S111 may be performed to supply molybdenum precursor gas into an ALD chamber. The molybdenum precursor may be carried into the ALD chamber with the aid of an inert gas. In example embodiments, the molybdenum precursor may be Mo(CO)₆, and a flow rate of the molybdenum precursor gas may range from 10 sccm to 100 sccm. Further, the ALD chamber may be controlled to have an internal temperature of 200° C., but example embodiments of the inventive concept are not limited thereto.

In example embodiments, in the step S115 of supplying the oxygen source gas, at least one of water, ozone, or oxygen plasma may be used as the oxygen source.

The purging step S113 may be performed to remove reaction gas (e.g., containing the molybdenum precursor), which is not participated in an adsorption process after the step S111, from the ALD chamber, and the purging step S117 may be performed to remove reaction gas (e.g., containing an oxygen source and side products), which is not participated in a reaction after the step S115, from the ALD chamber.

In exemplary embodiments, the second step may include a step S121 of supplying a tungsten precursor gas into the chamber, a step S123 of purging the chamber with an inert gas, a step S125 of supplying an oxygen source gas into the chamber, and a step S127 of purging the chamber with an inert gas. Further, the forming of the metal oxide alloy may include a step S129 of controlling repetition of the second step until the total repetition number of the second step reaches a predetermined cycling number (e.g., m).

The step S121 may be performed to supply the tungsten precursor gas into an ALD chamber. The tungsten precursor gas may be carried into the ALD chamber with the aid of an inert gas. In example embodiments, the tungsten precursor gas may be or include at least one of WH₂(iPrCp)₂ or W (CO)₆ and a flow rate of the tungsten precursor gas may range from 10 sccm to 100 sccm.

In example embodiments, the steps S123, S125, and S127 may be performed in substantially the same manner as those of the steps S113, S115, and S117 of the first step, but example embodiments of the inventive concept are not limited thereto.

In exemplary embodiments, the first step may be repeated until the total repetition number thereof reaches the predetermined cycling number of n, and the second step may be repeated until the total repetition number thereof reaches the predetermined cycling number of m, and the repetition of the first and second steps may be adjusted to control a composition ratio of metals constituting the metal sulfide alloy. In other words, by changing the ratio of n:m, it is possible to control the composition ratio of the metals contained in the metal sulfide alloy.

As an example, when the first and second steps were repeated one and six times, respectively (i.e., n:m=1:6), atomic percentages of molybdenum (Mo), tungsten (W), and sulfur (S) in Mo₍₁₋ₓ₎WₓS₂ were 6.9%, 26.5%, and 66.6%, respectively, and a ratio of Mo to W was 2:8. As other example, when the ratio of n:m was 1:2, atomic percentages of molybdenum (Mo), tungsten (W), and sulfur (S) in Mo₍₁₋ₓ₎WₓS₂ were 12.5%, 19.3%, and 68.2%, respectively, and a ratio of Mo to W was 4:6. As still other example, when the ratio of n:m was 3:1, atomic percentages of molybdenum (Mo), tungsten (W), and sulfur (S) in Mo₍₁₋ₓ₎WₓS₂ were 22.5%, 10.5%, and 67.0%, respectively, and a ratio of Mo to W was 7:3.

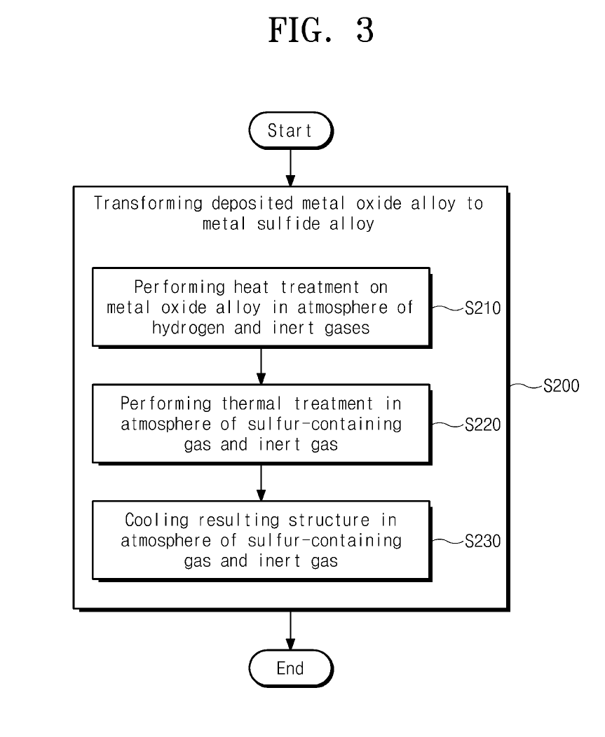

FIG. 3 is a flow chart illustrating a process of transforming the metal oxide alloy to a metal sulfide alloy, according to example embodiments of the inventive concept.

As shown in FIG. 3, according to example embodiments of the inventive concept, a process of transforming a metal oxide alloy to a metal sulfide alloy may include a step S210 of performing a heat treatment on the metal oxide alloy in an atmosphere of hydrogen and inert gases, a step S220 of performing a thermal treatment the metal oxide alloy in an atmosphere of sulfur-containing gas and inert gas, and a step S230 of cooling the resulting structure in an atmosphere of sulfur-containing gas and inert gas.

The heat treatment step S210 may be performed to remove organic contaminants from a surface of an oxide layer, and the thermal treatment step S220 may be performed to sulfurate the oxide alloy and improve crystallinity of the resulting sulfide alloy.

According to example embodiments of the inventive concept, the heat treatment step S210 may be performed at a temperature of 200-600° C. for 30-60 minutes, in the atmosphere of hydrogen gas and inert gas. Here, each of the hydrogen gas and the inert gas may be supplied at a flow rate of 10-100 sccm.

According to example embodiments of the inventive concept, the thermal treatment step S220 may be performed at a temperature of 600-1000° C. for 30-60 minutes, in the atmosphere of sulfur-containing gas and inert gas. Here, each of the sulfur-containing gas and the inert gas may be supplied at a flow rate of 10-100 sccm.

According to example embodiments of the inventive concept, the cooling step S230 may be performed at the room temperature, and each of the sulfur-containing gas and the inert gas may be supplied at a flow rate of 10-100 sccm. In example embodiments, the sulfur-containing gas may be hydrogen sulfide (H₂S).

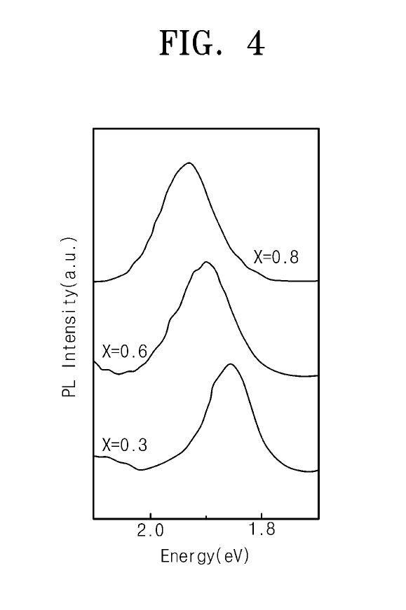

FIG. 4 is a graph showing a change in band gap of Mo₍₁₋ₓ₎WₓS₂ according to example embodiments of the inventive concept, depending on a metal composition ratio thereof.

FIG. 4 shows that, in the metal sulfide alloy of Mo₍₁₋ₓ₎WₓS₂ according to example embodiments of the inventive concept, an increase in content x of tungsten led to a shift toward a band gap energy of 2.0 eV.

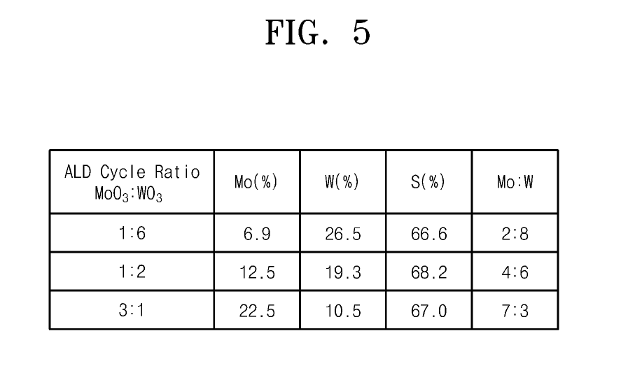

FIG. 5 is a table showing a ratio of molybdenum to tungsten in Mo₍₁₋ₓ₎WₓS₂, depending on a ratio in the cycling numbers of molybdenum oxide and tungsten oxide.

FIG. 5 shows that a composition ratio of metals constituting a metal sulfide alloy can be changed by adjusting the cycling numbers of the ALD steps for the molybdenum oxide and the tungsten oxide or by changing the ratio of n:m (e.g., in FIG. 1), when the step of forming the metal oxide alloy is performed.

As an example, when the first and second steps were repeated one and six times, respectively (i.e., n:m=1:6), atomic percentages of molybdenum (Mo), tungsten (W), and sulfur (S) in Mo₍₁₋ₓ₎WₓS₂ were 6.9%, 26.5%, and 66.6%, respectively, and a ratio of Mo to W was 2:8 (in a first embodiment). As other example, when the ratio of n:m was 1:2, atomic percentages of molybdenum (Mo), tungsten (W), and sulfur (S) in Mo₍₁₋ₓ₎WₓS₂ were 12.5%, 19.3%, and 68.2%, respectively, and a ratio of Mo to W was 4:6 (in a second embodiment). As still other example, when the ratio of n:m was 3:1, atomic percentages of molybdenum (Mo), tungsten (W), and sulfur (S) in Mo₍₁₋ₓ₎WₓS₂ were 22.5%, 10.5%, and 67.0%, respectively, and a ratio of Mo to W was 7:3 (in a third embodiment).

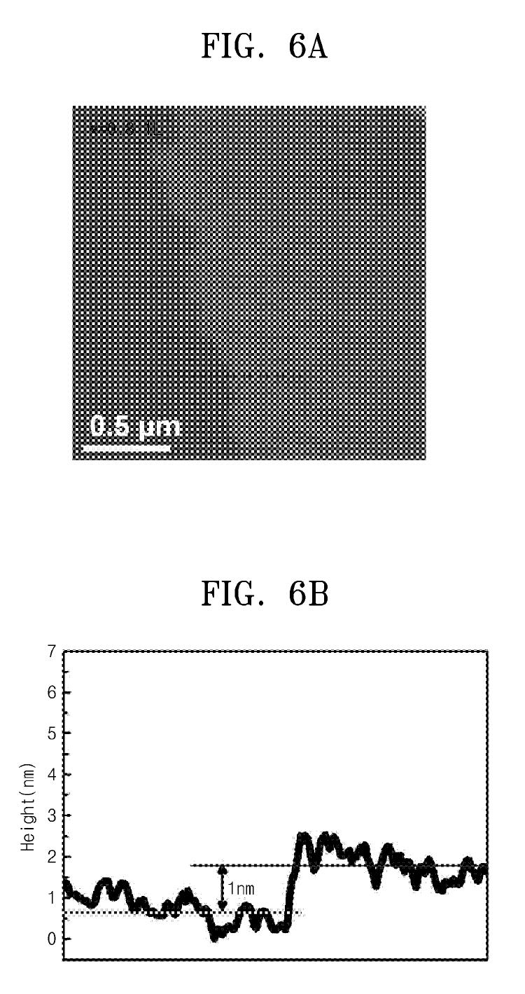

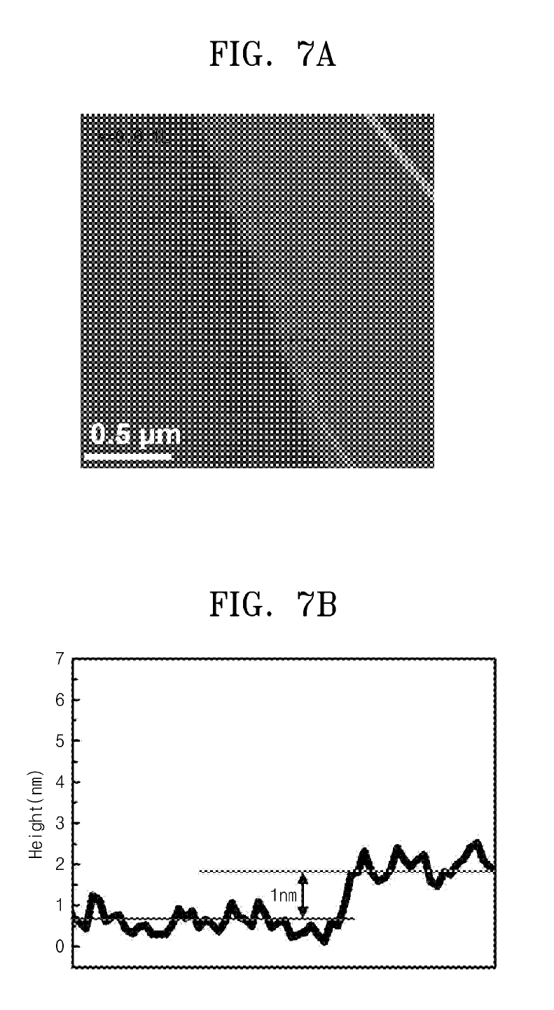

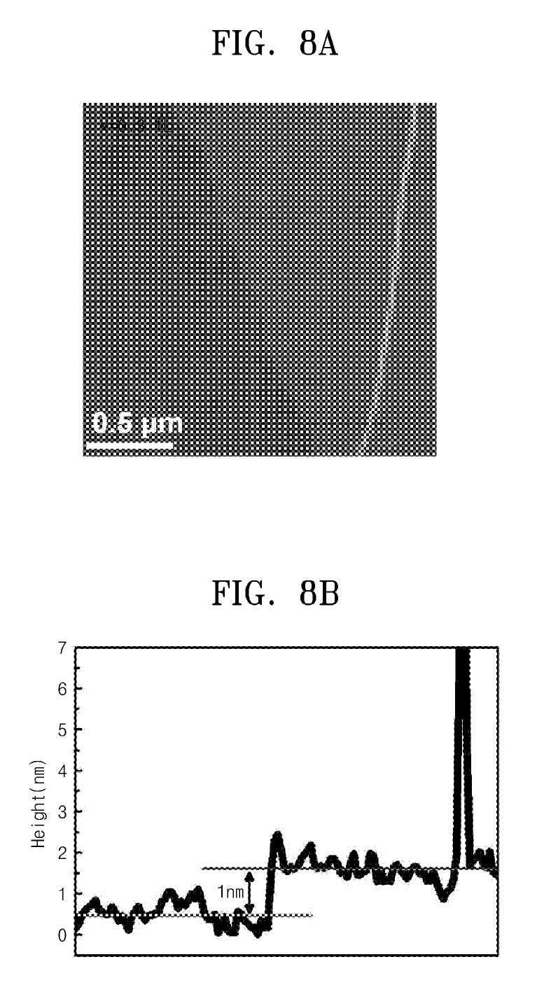

FIGS. 6A, 7A, and 8A are atomic force microscope (AFM) images obtained from Mo₍₁₋ₓ₎WₓS₂ layers, which were formed by methods according to first, second, and third embodiments of the inventive concept, and FIGS. 6B, 7B, and 8B are graphs showing spatial variations in thicknesses of thereof. In the first, second, and third embodiments of the inventive concept, a single layer of Mo₍₁₋ₓ₎WₓS₂ was formed by once performing the first and second steps.

Referring to FIGS. 6A, 7A, and 8A, the layers of Mo₍₁₋ₓ₎WₓS₂ synthesized by the methods according to the first, second, and third embodiments of the inventive concept were uniformly formed, except for a slight wrinkle formed during the sulfuration step. Referring to FIGS. 6B, 7B, and 8B, all of the single layers of Mo₍₁₋ₓ₎WₓS₂ synthesized by the methods according to the first, second, and third embodiments of the inventive concept had a thickness of about 1 nm, independent of the tungsten content (i.e., the value of x).

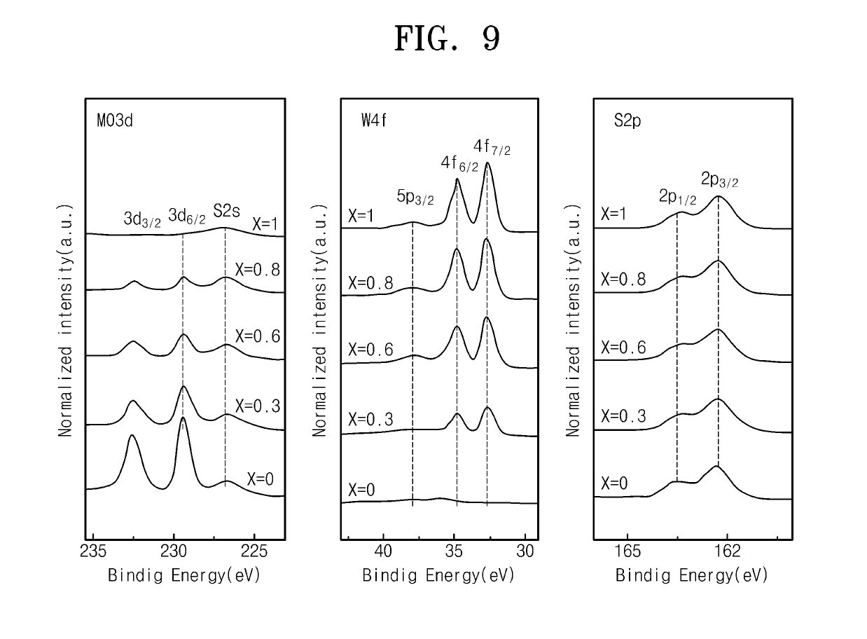

FIG. 9 is a diagram showing X-ray Photoelectron Spectroscopy (XPS) images obtained from metal sulfide alloys according to example embodiments of the inventive concept.

The composition analysis on the synthesized metal sulfide alloys shows that, as shown in FIG. 9, all of molybdenum (Mo), tungsten (W), and sulfur (S) were contained in each of the synthesized metal sulfide alloys according to the example embodiments of the inventive concept, and the content of sulfur was substantially constant, independent of the content of molybdenum or tungsten.

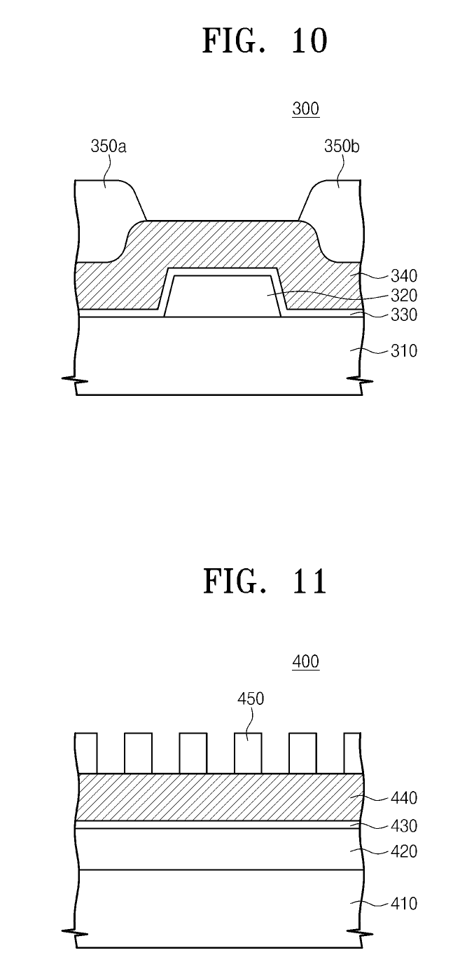

FIG. 10 is a sectional view illustrating an example of a transistor 300, according to example embodiments of the inventive concept. Although a bottom gate type transistor is illustrated as an example of the transistor in FIG. 10, but example embodiments of the inventive concept are not limited thereto. For example, the metal sulfide alloy according to example embodiments of the inventive concept can also be used for a channel layer of a top gate type transistor.

Referring to FIG. 10, a gate 320 may be provided on a substrate 310, and a gate insulating layer 330 may be provided to cover the substrate 310 provided with the gate 320. A channel layer 340 may be provided on the gate insulating layer 330, and a source electrode 350a and a drain electrode 350b may be provided on the channel layer 340. As an example, the channel layer 340 may include the metal sulfide alloy formed by the method according to example embodiments of the inventive concept.

FIG. 11 is a sectional view illustrating an example of a solar cell 400, according to example embodiments of the inventive concept.

Referring to FIG. 11, a first electrode 420, a charge transport layer 430, an active layer 440, and an second electrode 450 may be formed on a substrate 410. As an example, the active layer 440 may include the metal sulfide alloy formed by the method according to example embodiments of the inventive concept.

According to example embodiments of the inventive concept, it is possible to improve thickness controllability and large-area uniformity of a metal sulfide alloy to be deposited.

According to example embodiments of the inventive concept, by adjusting a metal composition ratio of metal sulfide alloy, it is possible to form a metal sulfide alloy with a controllable band gap.

While example embodiments of the inventive concepts have been particularly shown and described, it will be understood by one of ordinary skill in the art that variations in form and detail may be made therein without departing from the spirit and scope of the attached claims.

What is claimed is:

1. A method for forming a metal sulfide alloy, comprising:
forming a metal oxide alloy on a substrate using an atomic layer deposition (ALD) process; and
transforming the metal oxide alloy to a metal sulfide alloy.

2. The method of claim 1, wherein the forming of the metal oxide alloy comprises:
a first step for forming molybdenum oxide (MoO₃) using an ALD process; and
a second step for forming tungsten oxide (WO₃) using an ALD process,
wherein a process cycle comprising both the first and the second steps is performed at least one time.

3. The method of claim 2, wherein each of the first step and the second step comprising controlling a composition ratio of metals of the metal oxide alloy to adjust a band gap of the metal sulfide alloy.

4. The method of claim 3, wherein the composition ratio of metals of the metal oxide alloy is controlled by changing the cycling numbers of the ALD processes in the first and the second steps.

5. The method of claim 2, wherein the first step comprises:
supplying a molybdenum precursor comprising Mo(CO)₆ into an ALD chamber; and
supplying an oxygen precursor into the ALD chamber.

6. The method of claim 2, wherein the second step comprises:
supplying a tungsten precursor comprising WH₂(iPrCp)₂ into an ALD chamber; and
supplying an oxygen precursor into the ALD chamber.

7. The method of claim 1, wherein the forming of the metal oxide alloy comprises forming the metal oxide alloy having a chemical structure of Mo₍₁₋ₓ₎WₓP₃(0<x<1).

8. The method of claim 1, wherein the transforming of the metal oxide alloy to the metal sulfide alloy comprises performing a thermal treatment on the substrate provided with the metal oxide alloy in an atmosphere of sulfur-containing gas and inert gas.

9. The method of claim 8, wherein the thermal treatment is performed at a temperature of 600° C. to 1000° C. for 30 minutes to 60 minutes.

10. The method of claim 9, wherein in the thermal treatment, the sulfur-containing gas is supplied at a flow rate of 10 sccm to 100 sccm and the inert gas is supplied at a flow rate of 10 sccm to 100 sccm.

11. The method of claim 8, further comprising performing a heat treatment on the substrate provided with the metal oxide alloy in an atmosphere of hydrogen gas and inert gas, before the thermal treatment is performed.

12. The method of claim 11, wherein the heat treatment is performed at a temperature of 200° C. to 600° C. for 30 minutes to 90 minutes.

13. The method of claim 12, wherein in the heat treatment, each of the hydrogen gas and the inert gas is supplied at a flow rate of 10 sccm to 100 sccm.

14. The method of claim 8, further comprising cooling the substrate in an atmosphere of sulfur-containing gas and inert gas, after the thermal treatment.

15. The method of claim 14, wherein in the cooling of the substrate, each of the sulfur-containing gas and the inert gas is supplied at a flow rate of 10 sccm to 100 sccm.

16. The method of claim 1, wherein the transforming of the metal oxide alloy to the metal sulfide alloy is performed to transform the metal oxide alloy to the metal sulfide alloy having a chemical structure of Mo₍₁₋ₓ₎WₓS₂(0<x<1).

17. A transistor, comprising:
a gate electrode on a substrate;
a gate insulating material on the gate electrode;
a channel layer on the gate insulating material, the channel layer comprising a metal sulfide alloy; and
a source electrode on the channel layer and a drain electrode on the channel layer.

18. A solar cell, comprising:
a first electrode on a substrate;
an active layer on the first electrode, the active layer comprising a metal sulfide alloy; and
a second electrode on the active layer.
